(19) United States
(12) Patent Application Publication
(10) Pub. No.: US 2025/0125192 A1
(43) Pub. Date: Apr. 17, 2025

(54) AIR GAP STRUCTURE IN INTERCONNECT WITH TOP VIA

(71) Applicant: International Business Machines Corporation, Armonk, NY (US)

(72) Inventors: Ashim Dutta, Clifton Park, NY (US); Katherine Luedders, Cohoes, NY (US); Chih-Chao Yang, Glenmont, NY (US)

(21) Appl. No.: 18/380,478

(22) Filed: Oct. 16, 2023

(51) Int. Cl. H01L 21/768; H01L 23/528; H01L 23/532

(52) U.S. Cl. CPC H01L 21/7682; H01L 21/76834; H01L 21/76885; H01L 23/528; H01L 23/5329

(57) ABSTRACT

A back-end-of-the-line (BEOL) interconnect structure is provided that includes a top via structure located on a metal line. An air gap is located adjacent to, and around, the metal line and top via structure. This air gap includes a lower portion adjacent to the metal line and an upper portion adjacent to the top via structure. Such an air gap can extend BEOL interconnect scaling for 2 nm technology node and below. Methods of forming such an BEOL interconnect structure are also provided.

### BACKGROUND

The present application relates to semiconductor technology, and more particularly to a back-end-of-the-line (BEOL) interconnect structure containing air gaps located adjacent to metal lines and top via structures, and method of forming such structures.

Generally, BEOL interconnect devices include a plurality of circuits which form an integrated circuit (IC) fabricated on a BEOL interconnect substrate. A complex network of signal paths will normally be routed to connect the circuit elements distributed on the surface of the substrate. Efficient routing of these signals across the device requires formation of multilevel or multilayered schemes, such as, for example, single or dual damascene wiring structures, i.e., interconnects. The design and layout of BEOL interconnects on an IC can be vital to its proper function, performance, power efficiency, reliability, and fabrication yield.

Within typical BEOL interconnect structures, electrically conductive metal vias run perpendicular to an interconnect substrate and electrically conductive metal lines run parallel to the interconnect substrate. Typically, the electrically conductive metal vias are present beneath the electrically conductive metal lines and both features are embedded within an interconnect dielectric material layer.

### SUMMARY

A BEOL interconnect structure is provided that includes a top via structure located on a metal line. An air gap is located adjacent to, and around, the metal line and the top via structure. This air gap includes a lower portion adjacent to the metal line and an upper portion adjacent to the top via structure. Such an air gap can extend BEOL interconnect scaling for 2 nm technology node and below. Methods of forming such an BEOL interconnect structure are also provided.

In one aspect of the present application, a BEOL interconnect structure is provided. In one embodiment of the present application, the BEOL interconnect structure includes a top via structure located on a metal line. An air gap is present adjacent to, and around, both the metal line and the top via structure. Notably, the air gap has a lower air gap portion that is located adjacent to the metal line and an upper air gap portion that is located adjacent to the top via structure.

In another aspect of the present application, methods of forming a BEOL interconnect structure are provided. In one embodiment, the method includes forming a top via structure on a metal line; forming a first dielectric liner on all physically exposed surfaces of the metal line and the top via structure; forming a sacrificial liner around the metal line and top via structure and on the first dielectric liner; forming a second dielectric liner on the sacrificial liner; forming an interlayer dielectric layer on the second dielectric liner; removing the sacrificial liner to form an air gap region; and forming an air gap region sealant layer to close the air gap region forming an air gap.

In another embodiment, the method includes forming a top via structure on a metal line; forming a dielectric liner on all physically exposed surfaces of the metal line and the top via structure; forming a sacrificial liner around the metal line and the top via structure and on the dielectric liner; forming, by a selective deposition process, a dielectric layer on a portion of the dielectric liner; forming an interlayer dielectric layer on the dielectric layer; removing the sacrificial liner to form an air gap region; and forming an air gap region sealant layer to close the air gap region forming an air gap.

### BRIEF DESCRIPTION OF THE DRAWINGS

FIG. 1 is a cross sectional view of an exemplary structure that can be employed in accordance with an embodiment of the present application, the exemplary structure including metal lines and a top via structure located on a substrate.

FIG. 2 is a cross sectional view of the exemplary structure shown in FIG. 1 after forming a first (inner) dielectric liner on all physically exposed surfaces of the metal lines and the top via structure.

FIG. 3 is a cross sectional view of the exemplary structure shown in FIG. 2 after forming a sacrificial liner on the first dielectric liner.

FIG. 4 is a cross sectional view of the exemplary structure shown in FIG. 3 after removing the sacrificial liner from horizontal surfaces of the structure.

FIG. 5 is a cross sectional view of the exemplary structure shown in FIG. 4 after forming a second (outer) dielectric liner.

FIG. 6 is a cross sectional view of the exemplary structure shown in FIG. 5 after forming an interlayer dielectric (ILD) layer.

FIG. 7 is a cross sectional view of the exemplary structure shown in FIG. 6 after removing the remaining sacrificial liner to form air gap regions.

FIG. 8 is a cross sectional view of the exemplary structure shown in FIG. 7 after forming an air gap region sealant layer to close the air gap regions forming air gaps.

FIG. 9 is a cross sectional view of the exemplary structure shown in FIG. 4 after select deposition of a dielectric layer on dielectric surfaces of the structure.

FIG. 10 is a cross sectional view of the exemplary structure shown in FIG. 9 after forming an ILD layer.

FIG. 11 is a cross sectional view of the exemplary structure shown in FIG. 10 after removing the remaining sacrificial liner to form air gap regions.

FIG. 12 is a cross sectional view of the exemplary structure shown in FIG. 11 after forming an air gap region sealant layer to close the air gap regions forming air gaps.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

BEOL interconnects using top vias appear to be defining the next generation technology roadmap for scaling with better RC performance. RC is the product of resistance, R, and capacitance, C, which needs to be low to create fast chips since device speed is inversely proportional to RC (lower RC generally provides faster devices). One of the main challenges in RC reduction approach is decreasing the dielectric constant of the interconnect dielectric material that embeds the metal vias and metal lines. There are however no known low dielectric constant (k) materials that are robust enough to provide a time-dependent dielectric breakdown (TDDB) benefit. A new approach to reduce RC in BEOL interconnect structures including top via structures is needed.

In the present application, the above problems (including RC reduction) are solved by embedding air gaps around both the metal lines and the top via structures. The air gaps that are formed in the present application have well-defined and consistent dimensions which can be maintained uniformly across a die, field and wafer. The air gaps are located between each metal line and each air gap extends around a top via structure that is located on the metal lines.

In one aspect of the present application, a BEOL interconnect structure is provided. In one embodiment of the present application (see, for example, FIGS. 8 and 12), the BEOL interconnect structure includes a top via structure 14 located on a metal line 12. An air gap 25 is present adjacent to, and around, both the metal line 12 and the top via structure 14. Notably, the air gap 25 has a lower air gap portion P1 that is located adjacent to the metal line 12 and an upper air gap portion P2 that is located adjacent to the top via structure 14. By extending this air gap to be around the top via structure 14, a reduction of the effective dielectric constant of the dielectric around the top via structure is obtained. This effective dielectric constant reduction is more effective when the top via structures are placed in close proximity to each other. This helps in reducing the effective capacitance of the whole interconnect structure. This, in turn, reduces the RC of the interconnect structure.

In embodiments of the present application, the lower air gap portion P1 of the air gap 25 has a first width, and the upper air gap portion P2 of the air gap 25 has a second width, wherein the first width is substantially equal to, or different from, the second width. In the illustrated embodiment shown in FIGS. 8 and 12, the first width of the lower air gap portion P1 is greater than the second width of the upper air gap portion P2. In another embodiment, not illustrated, the first width of the lower air gap portion P1 is less than the second width of the upper air gap portion P2. In yet another embodiment, not illustrated, the first width of the lower air gap portion P1 is substantially equal to the second width of the upper air gap portion P2.

In embodiments of the present application (see, for example, FIGS. 8 and 12), the air gap 25 extends substantially to a topmost surface of the top via structure 14. By extending the air gap 25 to the topmost surface of the top via structure, reduction in RC can be obtained.

In embodiments of the present application (see, for example, FIGS. 8 and 12), the structure further includes additional metal lines 12 which are located adjacent to the metal line 12 that is located beneath the top via structure 14. In such embodiments, additional air gaps 25 are located between each of the additional metal lines 12. Although not shown, each additional metal line 12 would include one or more top via structures 14 located thereon and the additional air gaps 25 would extend around the additional top via structures as well. The additional top via structures are not shown because they are not in the same plane of the illustrated cross section shown in FIGS. 8 and 12.

In embodiments of the present application (see, for example, FIG. 8), a portion of the air gap 25 is sandwich between a first dielectric liner 16 and a second dielectric liner 20.

In embodiments of the present application (see, for example, FIG. 8), the first dielectric liner 16 is located on a sidewall of the metal line 12 and a sidewall of the top via structure 14.

In embodiments of the present application (see, for example, FIG. 8), the structure further includes an interlayer dielectric layer 22 located on the second dielectric liner 20 and the interlayer dielectric layer 22 has a topmost surface that is substantially coplanar with a topmost surface of the top via structure 14.

In embodiments of the present application (see, for example, FIG. 8), the structure further includes an air gap region sealant layer 26 located on the interlayer dielectric layer 22 and on top of the top via structure 14, wherein the air gap region sealant layer 26 extends over the air gap 25. The air gap region sealant layer 26 seals the air gap region that is provided and forms the air gap 25 of the present application.

In embodiments of the present application (see, for example, FIGS. 8 and 12), the air gap 25 is spaced apart from the metal line 12 and top via structure 14 by a dielectric liner (i.e., first dielectric liner 16).

In embodiments of the present application (see, for example, FIGS. 8 and 12), the structure can include an additional metal line 12 located adjacent to the metal line 12 that is located beneath the top via structure 14.

In embodiments of the present application (see, for example, FIG. 12), the structure can further include a dielectric layer 28B located above the additional metal line 12, wherein dielectric layer 28B has a middle portion having a first thickness, and end portions having a second thickness, wherein the first thickness is greater than the second thickness.

In embodiments of the present application (see, for example, FIG. 12), the structure further includes an interlayer dielectric layer 22 located on the dielectric layer 28B and having a topmost surface that is substantially coplanar with a topmost surface of the top via structure 14.

In embodiments of the present application (see, for example, FIG. 12), the structure further includes an air gap region sealant layer 26 located on the interlayer dielectric layer 22 and on top of the top via structure 14, wherein the air gap region sealant layer 26 extends over the air gap 25. The air gap region sealant layer 26 seals the air gap region that is provided and forms the air gap 25 of the present application.

In embodiments of the present application (see, for example, FIGS. 8 and 12), the metal line 12 including the top via structure 14 is located on a surface of a substrate 10, wherein the substrate 10 includes at least one lower interconnect level, a middle-of-the line (MOL) level, a front-end-of-the-line (FEOL) level or any combination of said levels.

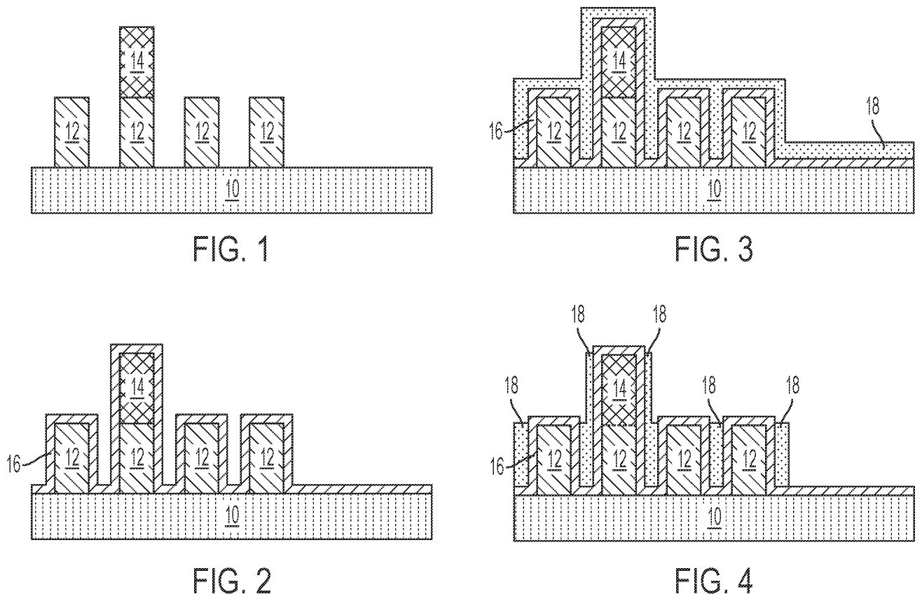

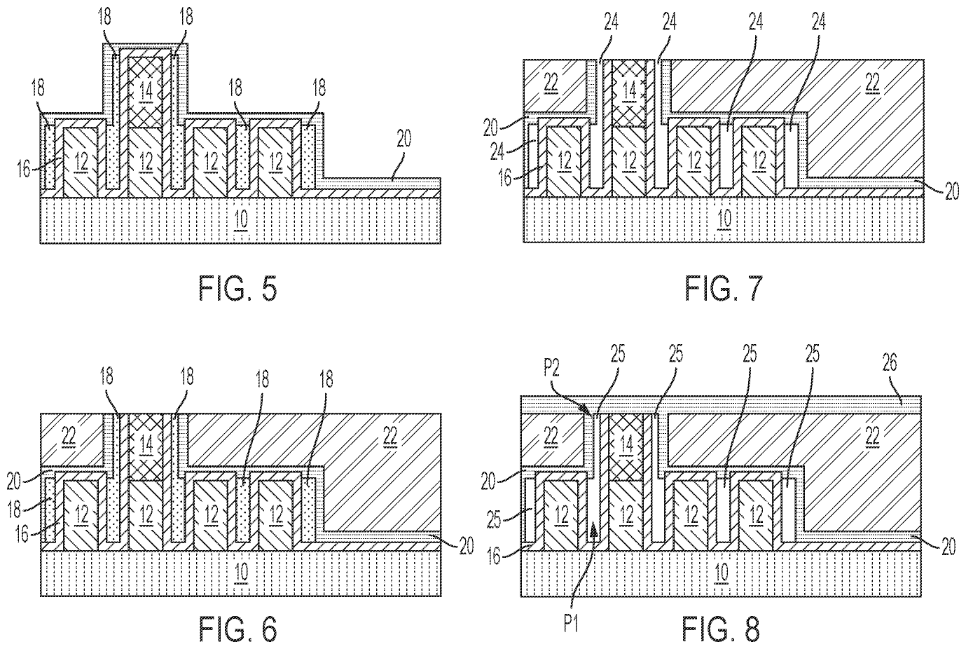

In the present application, FIGS. 1-8 represents a first method embodiment of the present application. This first method embodiment includes forming top via structure 14 on a metal line 12 (See, FIG. 1); forming a first dielectric liner 16 on all physically exposed surfaces of the metal line 12 and the top via structure 14 (See, FIG. 2); forming a sacrificial liner 18 around the metal line 12 and the top via structure 14 and on the first dielectric liner 16 (See, FIGS. 3-4); forming a second dielectric liner 20 on the sacrificial liner 18 (See, FIG. 5); forming an interlayer dielectric layer 22 on the second dielectric liner 20 (See, FIG. 6); removing the sacrificial liner 18 to form an air gap region 24 (See, FIG. 7); and forming an air gap region sealant layer 26 to close the air gap region 24 forming an air gap 25 (See, FIG. 8).

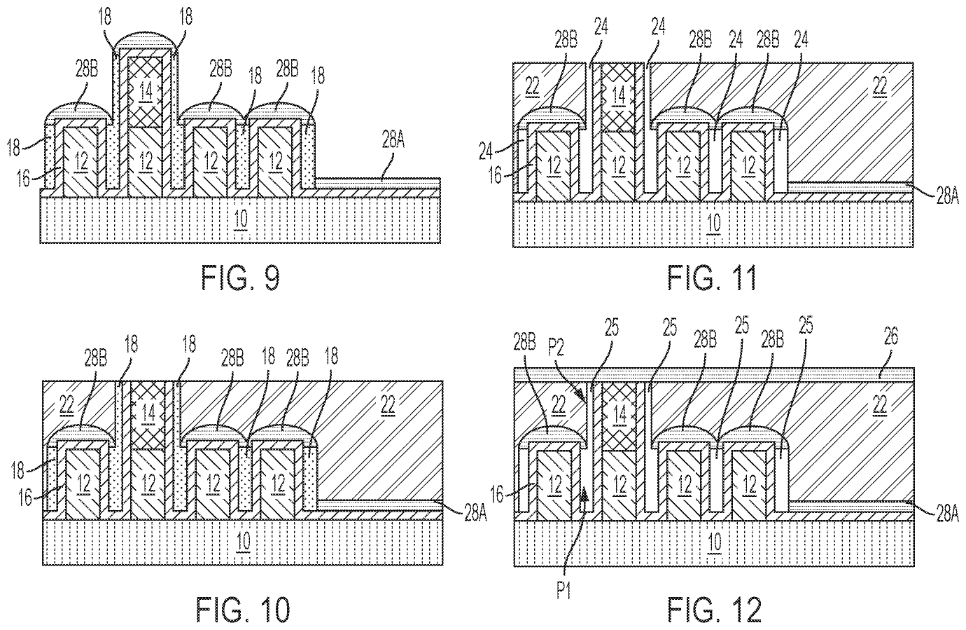

FIGS. 1-4 and 9-12 represents a second method embodiment of the present application. This second method embodiment includes forming a top via structure 14 on a metal line 12 (See, FIG. 1); forming a dielectric liner (i.e., the first dielectric liner 16) on all physically exposed surfaces of the metal line 12 and the top via structure 14 (See, FIG. 2); forming a sacrificial liner 18 around the metal line 12 and the top via structure 14 and on the dielectric liner (See, FIGS. 3-4); forming, by a selective deposition process, a dielectric layer 22B on a portion of the dielectric layer (See, FIG. 9); forming an interlayer dielectric layer 22 on the dielectric layer 22B (See, FIG. 10); removing the sacrificial liner 18 to form an air gap region 24 (See, FIG. 11); and forming an air gap region sealant layer 26 to close the air gap region 24 forming an air gap 25 (See, FIG. 12).

Referring first to FIG. 1, there is illustrated an exemplary structure that can be employed in accordance with an embodiment of the present application, the exemplary structure includes metal lines 12 located on substrate 10. The illustrated structure further includes a top via structure 14 that is located on one of the metal lines 12. It is noted that each of the metal lines 12 illustrated in FIG. 1 would include a top via structure. These additional top via structures are not in the same plane of the cross section illustrated in FIG. 1 as such they are not shown in the drawings of the present application. By way of an example, the drawings illustrate the presence of four metal lines 12 and one top via structure 14. The present application works with any number of metal lines 12 and top via structures 14. It is noted that the metal lines 12 and the top via structure 14 are present in a same interconnect level.

The substrate 10 can include at least one lower interconnect level, a middle-of-the line (MOL) level, a front-end-of-the-line (FEOL) level or any combination of said levels. For example, the substrate 10 can include, a lower interconnect level, a MOL level located beneath the lower interconnect level and a FEOL level located beneath the MOL level. The at least one lower interconnect level and the MOL level can include electrically conductive structures (i.e., metal lines and metal vias) embedded in a dielectric material layer. The FEOL level can include a semiconductor substrate having one or more semiconductor devices (such as, for example, transistors) formed thereon. The at least one lower interconnect level, the MOL level and the FEOL level can be formed utilizing materials and techniques that are well known to those skilled in the art. So not to obscure the methods of the present application, the materials and techniques used in providing the at least one lower interconnect level, the MOL level and the FEOL level are not described in detail in the present application.

In the present application, and due to the subtractive etch that is used in forming the metal lines 12 and the top via structure 14, each metal line 12/top via structure 14 combination is of unitary construction (i.e., single work piece) and is composed of a same electrically conductive material throughout. Notably, each of the metal lines 12 and the top via structure 14 is composed of an electrically conductive metal or electrically conductive metal alloy. Exemplary electrically conductive metals that can be used in providing the metal lines 12 and the top via structure 14 include, but are not limited to, aluminum (Al), tungsten (W), cobalt (Co), ruthenium (Ru), rhodium (Rh), or platinum (Pt).

The metal lines 12 and the top via structure 14 are formed utilizing a subtractive etching process that is well known to those skilled in the art. The subtractive etching process is performed on a blanket layer of one of the above mentioned electrically conductive materials. This blanket layer can be formed by utilizing a deposition process such as, for example, chemical vapor deposition (CVD), plasma enhanced chemical vapor deposition (PECVD), physical vapor deposition (PVD), plating or sputtering. Following this blanket layer formation, metal lines 12 are patterned by subtractive patterning utilizing an etch such as, for example, reactive ion etching (RIE). A sacrificial dielectric is then deposited using CVD, PECVD or flowable CVD to fill the gap between metal lines 12, and thereafter a planarization process such as, for example, chemical mechanical planarization (CMP) is employed. Next, via patterning is performed to form self-aligned metal vias (i.e., top via structures 14) on top of the metal lines 12. Following the via patterning process, the sacrificial dielectric that is present between each of the metal lines 12 is removed using dry etching or wet etching.

Referring now to FIG. 2, there is illustrated the exemplary structure shown in FIG. 1 after forming a first (inner) dielectric liner 16 on all physically exposed surfaces of the metal lines 12 and the top via structure 14. The first dielectric liner 16 is also formed on portions of the substrate 10 that are not covered by the metal lines 12.

The first dielectric liner 16 is composed of a first dielectric liner material such as, for example, silicon oxide (SiOₓ), silicon nitride, SiC, SiCN or SiCO. The first dielectric liner 16 is formed by a deposition process such as, for example, CVD, PECVD, atomic layer deposition (ALD) or plasma enhanced atomic layer deposition (PEALD). In some embodiments, the first dielectric liner 16 is conformal liner that is formed by a conformal deposition process such as ALD. The term “conformal liner” denotes a liner whose thickness along a horizontal surface of a material layer/structure is the same as the thickness along a vertical surface of the material layer/structure.

Referring now to FIG. 3, there is illustrated the exemplary structure shown in FIG. 2 after forming a sacrificial liner 18 on the first dielectric liner 16. The sacrificial liner 18 is formed around the metal lines 12 and the top via structure 14. The sacrificial liner 18 is composed of a dielectric material or conducting material that can be selectively removed compared to the first dielectric liner 12. Exemplary materials that can be used as the sacrificial liner 18 include, but are not limited to, TiOₓ, TiN or an organic polymer. The sacrificial liner 18 is formed by a deposition process such as, for example, CVD, PECVD, ALD or PEALD. Note that the sacrificial liner 18 follows the contour of first dielectric liner 16.

Referring now to FIG. 4, there is illustrated the exemplary structure shown in FIG. 3 after performing an isotropic etch or etch back process on the sacrificial liner 18. The etch back process removes the sacrificial liner 18 from all horizontal surfaces of the exemplary structure, while leaving the sacrificial liner 18 on vertical surfaces of the exemplary structure. Notably, and after performing the etch back process, the sacrificial liner 18 remains on the a sidewall of the top via structure 14 as well as on a sidewall of each of the metal lines 12.

Referring now to FIG. 5, there is illustrated the exemplary structure shown in FIG. 4 after forming a second (outer) dielectric liner 20. The second dielectric liner 20 is composed of a second dielectric liner material which can be compositionally the same as, or compositionally different from the first dielectric liner material. The second dielectric liner material is compositionally different from the material that provides the sacrificial liner 18. Exemplary, second dielectric liner materials that provides the second dielectric liner 20 include, but are not limited to, silicon oxide (SiOₓ), silicon nitride, SiC, SiCN or SiCO. The second dielectric liner 20 is formed by a deposition process such as, for example, CVD, PECVD, ALD or PEALD. In some embodiments, the second dielectric liner 20 is conformal liner that is formed by a conformal deposition process such as ALD.

Referring now to FIG. 6, there is illustrated the exemplary structure shown in FIG. 5 after forming an ILD layer 22. The ILD layer 22 can be composed of an inorganic dielectric material or an organic dielectric material. In some embodiments, the ILD layer 22 can be porous. In other embodiments, the ILD layer 22 can be non-porous. Examples of suitable dielectric materials that may be employed as the ILD layer 22 include, but are not limited to, silicon oxide (SiOₓ), silicon nitride, undoped silicate glass (USG), fluorosilicate glass (FSG), borophosphosilicate glass (BPSG), a spin-on low-k dielectric, a chemical vapor deposition (CVD) low-k dielectric, or any combination thereof. The term “low-k” as used throughout the present application denotes a dielectric material that has a dielectric constant of less than 4.0 (all dielectric constants mentioned herein are relative to a vacuum unless otherwise noted). The ILD layer 22 can be formed by a deposition process such as, for example, CVD, PECVD or spin-on coating, followed by a planarization process. The planarization process includes CMP and/or grinding. The planarization process stops on a topmost surface of the top via structure 14. Note that the planarization process removes all material that is formed on the topmost surface of the top via structure 14. The topmost surface of the top via structure 14 is reveled, i.e., physically exposed, after planarization.

Referring now to FIG. 7, there is illustrated the exemplary structure shown in FIG. 6 after removing the remaining sacrificial liner 18 to form air gap regions 24. The remaining sacrificial liner 18 can be removed utilizing a wet stripping process or other isotropic etching process (i.e., a vapor etch) that is selective in removing the remaining sacrificial liner 18. Voids or air gap regions 24 are formed by this removal step. The removal of the remaining sacrificial liner 18 can start from the physically exposed topmost surface of the remaining sacrificial liner 18 or from physical exposed sidewalls of the sacrificial liner 18 at the metal line ends (this would require forming a block mask on the exemplary structure prior to performing the removal step).

In the present application, each air gap region 24 is located between the metal lines 12 and around each top via structure 14. In the present application, each air gap region 24 has a bottom portion having a width that is substantially equal to, or different from, a width of an upper portion. In some embodiments, the width of the lower portion of the air gap region 14 is less than the width of the upper portion of the air gap region 24. In other embodiments, the width of the lower portion of the air gap region 14 is greater than the width of the upper portion of the air gap region 24. In other embodiments, the width of the lower portion of the air gap region 14 is substantially equal to greater the width of the upper portion of the air gap region 24.

Referring now to FIG. 8, there is illustrated the exemplary structure shown in FIG. 7 after forming an air gap region sealant layer 26 on the structure to close (seal) the air gap regions 24 forming air gaps 25. The air gap region sealant layer 26 is composed of a dielectric material such as, for example, SiC, Si₃N₄, SiOₓ, a carbon doped oxide, a nitrogen and hydrogen doped silicon carbide (SiC(N,H)) or a multilayered stack of at least one of the aforementioned dielectric materials. The dielectric material that provides the air gap region sealant layer 26 can be formed utilizing a deposition process such as, for example, CVD, PECVD, ALD, PEALD, chemical solution deposition or evaporation.

In some embodiments, each air gap 25 has a bottom portion having a width that is greater than a width of an upper portion. In other embodiments, each air gap 25 has a bottom portion having a width that is less than a width of an upper portion. In yet other embodiments, each air gap 25 has a bottom portion having a width that is substantially equal to a width of an upper portion. Each air gap 25 has a lower air gap portion P1 that is located adjacent to, and around, the metal line 12 and an upper air gap portion P2 that is located adjacent to, and around, the top via structure 14. By having this upper air gap portion P2, a reduction in RC can be obtained.

Referring now to FIG. 9, there is illustrated the exemplary structure shown in FIG. 4 after select deposition of a dielectric layer 28A, 28B on dielectric surfaces of the structure. In the present application, element 28A is a dielectric layer that has a planar topography as illustrated in FIG. 9. In the present application, element 28B is dielectric layer that has a shape of a mushroom cap. That is, dielectric layer 28B has a topography in which the thickness at a middle portion of dielectric layer 28B is thicker than end portions of dielectric layer.

The dielectric layer 28A, 28B is composed of one of the second dielectric liner materials mentioned above for the second dielectric liner 20. The dielectric layer 28A, 28B is formed by a selective deposition process such as, for example, ALD or PEALD proceeded by a self-assembled monolayer (SAM) containing it in order to inhibit deposition on the sacrificial liner 18.

Referring now to FIG. 10, there is illustrated the exemplary structure shown in FIG. 9 after forming an ILD layer 22, and planarization. The ILD layer 22 of this embodiment is the same as the ILD layer 22 mentioned in the previous embodiment. Thus the description including dielectric materials and methods of deposition made in the previous embodiment in regard to ILD layer 22 shown in FIG. 6 applies here for this embodiment. Planarization includes CMP and/or grinding. The planarization process stops on a topmost surface of the top via structure 14. The planarization the topmost surface of the top via structure 14 as well as a topmost surface of the remaining sacrificial liner 18. Note that the planarization process removes all material including dielectric layer 28B that is formed on the topmost surface of the top via structure 14.

Referring now to FIG. 11, there is illustrated the exemplary structure shown in FIG. 10 after removing the remaining sacrificial liner 18 to form air gap regions 24. The remaining sacrificial liner 18 can be removed utilizing a wet stripping process that is selective in removing the remaining sacrificial liner 18. Voids or air gap regions 24 are formed by this removal step. The removal of the remaining sacrificial liner 18 can removed starting from the physically exposed topmost surface of the remaining sacrificial liner 18 or from physical exposed sidewalls at the metal line ends (this would require forming a block mask on the exemplary structure prior to performing the removal step).

Referring now to FIG. 12, there is illustrated the exemplary structure shown in FIG. 11 after forming an air gap region sealant layer 26 to close the air gap regions 24 forming air gaps 25. The air gap region sealant layer 26 of this embodiment of the present application is the same as the air gap region sealant layer 26 of the previous embodiment of the present application. Thus the description including dielectric materials and methods of deposition made in the previous embodiment in regard to air gap region sealant layer 26 shown in FIG. 8 applies here for this embodiment of the present application.

In this embodiment, the air gaps 25 are the same as defined above for the previous embodiment are formed. The description including height, dimension, and location of the air gaps 25 for this embodiment are the same as described in the previous embodiment of the present application.

FIGS. 8 and 12 illustrated BEOL interconnect structures in accordance with the present application. These BEOL interconnect structures include a top via structure 14 located on a metal line 12, and an air gap 25 is located adjacent to, and around, both the metal line 12 and the top via structure 14. In accordance with the present application, the air gap 25 has a lower air gap portion P1 that is located adjacent to the metal line 12 and an upper air gap portion P2 that is located adjacent to the top via structure 14. By extending this air gap to be adjacent to the top via structure 14 a reduction in RC can be obtained.

In embodiments of the present application, air can be present in the air gaps 25. In other embodiments, the air can be vacuumed out of the air gaps 25.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A back-end-of-the-line (BEOL) interconnect structure comprising:
a top via structure located on a metal line; and
an air gap located adjacent to, and around, both the metal line and the top via structure, wherein the air gap has a lower air gap portion that is located adjacent to the metal line and an upper air gap portion that is located adjacent the top via structure.

2. The BEOL structure of claim 1, wherein the lower air gap portion of the air gap has a first width, and the upper air gap portion of the air gap has a second width, wherein the first width is different from the second width.

3. The BEOL structure of claim 2, wherein the first width is greater than the second width.

4. The BEOL structure of claim 1, wherein the air gap extends substantially to a topmost surface of the top via structure.

5. The BEOL structure of claim 1, wherein a portion of the air gap is sandwich between a first dielectric liner and a second dielectric liner.

6. The BEOL structure of claim 5, wherein the first dielectric liner is located on a sidewall of the metal line and a sidewall of the top via structure.

7. The BEOL structure of claim 5, further comprising an interlayer dielectric layer located on the second dielectric liner and having a topmost surface that is substantially coplanar with a topmost surface of the top via structure.

8. The BEOL structure of claim 7, further comprising an air gap region sealant layer located on the interlayer dielectric layer and on top of the top via structure, wherein the air gap region sealant layer extends over the air gap.

9. The BEOL structure of claim 1, wherein the air gap is spaced apart from the metal line and top via structure by a dielectric liner.

10. The BEOL structure of claim 9, further comprising an additional metal line located adjacent to the metal line that is located beneath the top via structure.

11. The BEOL structure of claim 10, further comprising a dielectric layer located above the additional metal line, wherein dielectric layer has a middle portion having a first thickness, and end portions having a second thickness, wherein the first thickness is greater than the second thickness.

12. The BEOL structure of claim 11, further comprising an interlayer dielectric layer located on the dielectric layer and having a topmost surface that is substantially coplanar with a topmost surface of the top via structure.

13. The BEOL structure of claim 12, further comprising an air gap region sealant layer located on the interlayer dielectric layer and on top of the top via structure, wherein the air gap region sealant layer extends over the air gap.

14. The BEOL structure of claim 1, further comprising a substrate located beneath the metal line, wherein the substrate comprises at least one lower interconnect level, a middle-of-the line (MOL) level, a front-end-of-the-line (FEOL) level or any combination of said levels.

15. A method of forming a back-end-of-the-line (BEOL) interconnect structure, the method comprising:
forming a top via structure on a metal line;
forming a first dielectric liner on all physically exposed surfaces of the metal line and the top via structure;
forming a sacrificial liner around the metal line and the top via structure and on the first dielectric liner;
forming a second dielectric liner on the sacrificial liner;
forming an interlayer dielectric layer on the second dielectric liner;
removing the sacrificial liner to form an air gap region; and
forming an air gap region sealant layer to close the air gap region forming an air gap.

16. The method of claim 15, wherein the air gap has a lower air gap portion that is located adjacent to the metal line and an upper air gap portion that is located adjacent to the top via structure.

17. The method of claim 16, wherein the lower air gap portion has a first width, and the upper air gap portion has a second width, wherein the first width is different from the second width.

18. The method of claim 17, wherein the first width is greater than the second width.

19. The method of claim 17, wherein the air gap extends substantially to a topmost surface of the top via structure.

20. The method of claim 15, wherein the removing of the sacrificial liner comprises a wet etch or an isotropic dry etch.

21. A method of forming a back-end-of-the-line (BEOL) interconnect structure, the method comprising:
forming a top via structure on a metal line;
forming a dielectric liner on all physically exposed surfaces of the metal line and the top via structure;
forming a sacrificial liner around the metal line and the top via structure and on the dielectric liner;
forming, by a selective deposition process, a dielectric layer on a portion of the dielectric layer;
forming an interlayer dielectric layer on the dielectric layer;
removing the sacrificial liner to form an air gap region; and
forming an air gap region sealant layer to close the air gap region forming an air gap.

22. The method of claim 21, wherein the air gap has a lower air gap portion that is located adjacent to the metal line and an upper air gap portion that is located adjacent to the top via structure.

23. The method of claim 22, wherein the lower air gap portion has a first width, and the upper air gap portion has a second width, wherein the first width is different from the second width.

24. The method of claim 21, wherein the air gap extends substantially to a topmost surface of the top via structure.

25. The method of claim 21, wherein the removing of the sacrificial liner comprises a wet etch or an isotropic dry etch
